(19) United States
(12) Patent Application Publication
(10) Pub. No.: US 2011/0049703 A1
(43) Pub. Date: Mar. 3, 2011

(54) Flip-Chip Package Structure

(76) Inventors: Jun-Chung Hsu, Taoyuan (TW); Shuo-Hsun Chang, Taoyuan (TW)

(21) Appl. No.: 12/547,475

(22) Filed: Aug. 25, 2009

(51) Int. Cl. H01L 23/498

(52) U.S. Cl. 257/737; 257/778; 257/E23.068

(57) ABSTRACT

A flip-chip (FC) package structure is provided. The FC package structure includes a substrate, a chip, a plurality of copper platforms, a plurality of copper bumps, a plating layer, a circuit layer and a solder mask layer. The copper bumps are disposed on the substrate. The copper platforms are stacked on the copper bumps. The plating layer covers the copper bumps and the copper platforms, for contacting with chip foot pads configured at a bottom of the chip. The FC package structure does not need to reserve a space for wire bonding, thus saving the area of the substrate. The copper platforms are stacked on the copper bumps, and are higher than the circuit pattern layer. Therefore, the chip is blocked up, and the gap between the chip and the substrate is enlarged, thus preventing the risk of configuring voids when filling the cladding material and improving the packaging yield.

### BACKGROUND OF THE INVENTION

1. Field of the Invention

The present invention relates generally to a flip-chip (FC) package structure, and more particularly, to an FC package structure configured with copper platform bumps.

2. The Prior Arts

FC packaging is a new generation of semiconductor packaging method. An FC package structure usually includes a substrate and a chip I/O. The substrate and the chip I/O are typically bonded one to another by welding to the wafer bump with tin and/or lead bumps provided on the substrate, for transmitting signals or power. The FC package structures were widely employed in fabricating chip products related to personal computers (PC), and are now more often used in fabricating chip package structures of handheld products such as mobile phones and MP3. Comparing with wire-bond type chip scale packaging method, which is conventionally and typically used for packaging the chips of present handheld consumer electronic products, gold stud bump FC packaging is adapted for advantageously saving the cost for preparing the wafer bump while remaining the electrical characteristics of the FC package structure, and achieving an improved processing capability by the fine bump pitch between gold stud bumps. Further, the FC package structure does not need to reserve the space for wire bonding, and thus the area of the substrate can be saved, and the product can be made smaller.

FIG. 1 is a schematic diagram illustrating a conventional FC package structure. Referring to FIG. 1, it shows a conventional FC package 1 including a conventional FC platform structure 4 including a substrate 40, a cladding material 7, and a chip 8. A copper bump 33 is configured on the substrate 40. The copper bump 33 is covered with a plating layer 34. A copper pillar foot pad 14 is configured at a bottom of the chip 8. The copper bump 33 is welded to the copper pillar foot pad 14. The cladding material 7 is filled between the chip 8 and the conventional FC platform structure 4.

FIG. 2 is a top view of the conventional FC package structure, in which the right drawing shows a partial enlarged detail of the left drawing. FIG. 3 is a longitudinal cross-sectional view of the conventional FC package structure along a line III-III of FIG. 2. FIG. 4 is a latitudinal cross-sectional view of the conventional FC package structure along a line IV-IV of FIG. 2. As shown in FIG. 2, the conventional FC platform structure 4 includes the substrate 40, a conventional peripheral FC pad region 30, and a solder mask layer 50. The conventional peripheral FC pad region 30 includes a plurality of conventional FC pads 31. Each conventional FC pad 31 includes a copper bump 33 and a plating layer 34 covering the copper bump 33. As shown in FIG. 4, the copper bump 33 is configured lower than the solder mask layer 50 for a certain height.

As shown in FIG. 1, a gap d1 remained between the chip 8 and the solder mask layer 50. However, according to the conventional technology, the gap d1 is very small, and the stuff of the cladding material 7 is often not fine enough. Therefore, the cladding material 7 is often jammed at the gap d1 between the chip 8 and the solder mask layer 50. In such a way, a void may be configured beneath the chip 8, which adversely affects the packaging yield.

### SUMMARY OF THE INVENTION

A primary objective of the present invention is to provide an FC package structure. The FC package structure includes a substrate, a chip, a plurality of copper platform bumps, a circuit pattern layer, a plating layer, and a solder mask layer. The copper platform bumps and the circuit pattern layer are disposed on the substrate. The copper platform bumps have a height higher than a height of the circuit pattern layer. Each copper platform bump includes a copper platform and a copper bump. The copper platform is stacked on the copper bump. The plating layer is plated on the copper platform bumps, for connecting with chip foot pad provided at a bottom of the chip. The FC package structure does not need to reserve a space for wire bonding and thus the area of the substrate can be saved, and the product can be made smaller.

Accordingly, the present invention is adapted for providing a solution of the problem of the conventional technology. According to the present invention, the copper platform bumps are configured with a height higher than the height of the circuit pattern layer. In such a way, the chip is blocked up, so that the gap between the chip and the substrate is enlarged, thus preventing the risk of configuring voids when filling the cladding material and improving the packaging yield.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram illustrating a conventional FC package structure;

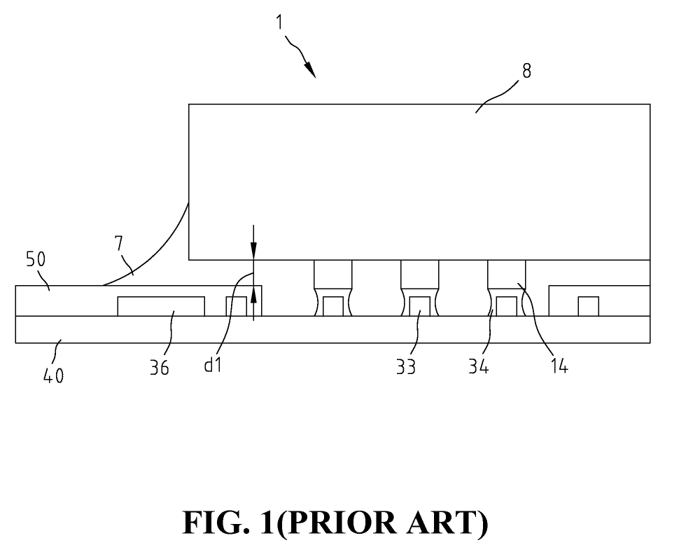

FIG. 2 is a top view of the conventional FC package structure;

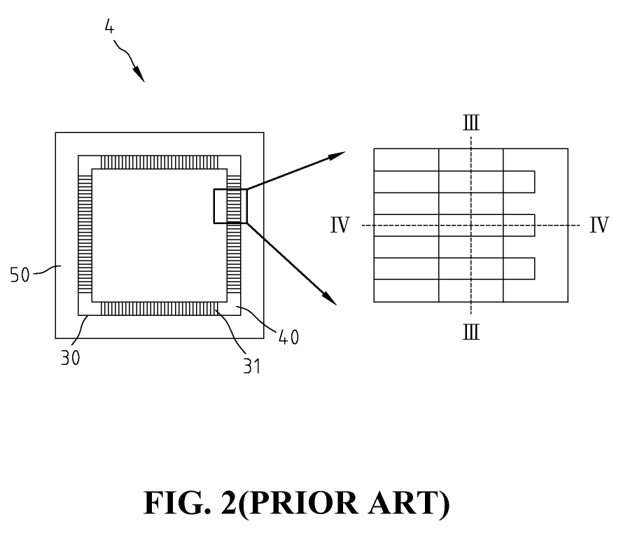

FIG. 3 is a longitudinal cross-sectional view of the conventional FC package structure;

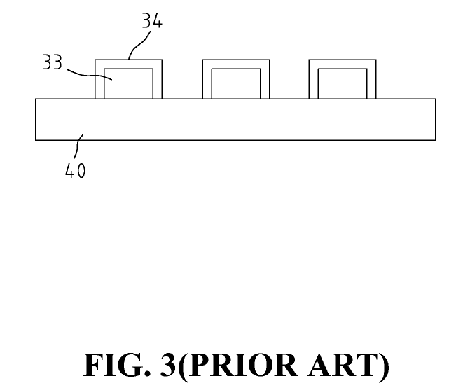

FIG. 4 is a latitudinal cross-sectional view of the conventional FC package structure;

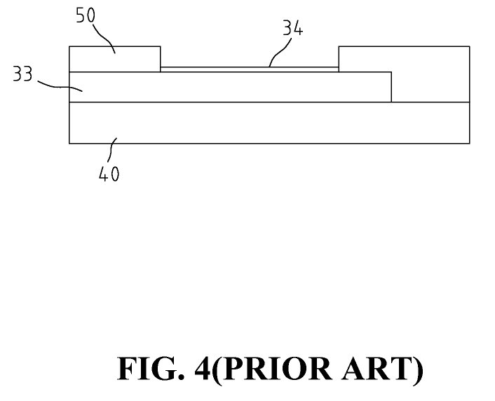

FIG. 5 is a schematic diagram illustrating an FC package structure of the present invention;

FIG. 6 is a schematic diagram of an embodiment of the present invention;

FIG. 7 is a longitudinal cross-sectional view of the embodiment of the present invention; and

FIG. 8 is a latitudinal cross-sectional view of the embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

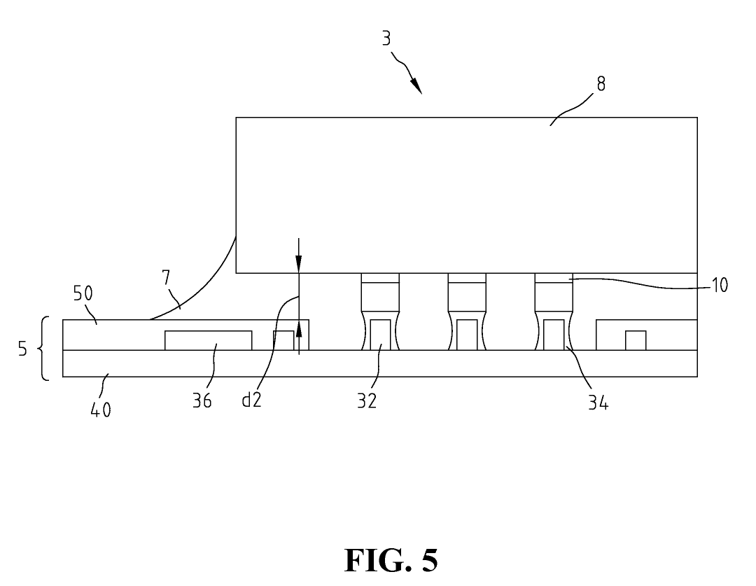

FIG. 5 is a schematic diagram illustrating an FC package structure of the present invention. Referring to FIG. 5, the present invention provides a flip-chip (FC) package structure 3. The FC package structure 3 includes a chip 8, an FC platform structure 5, and a cladding structure 7. The chip 8 includes a plurality of chip foot pads 10 disposed at a bottom of the chip 8. The FC platform structure 5 includes a substrate 40, a plurality of copper platform bumps 32, a plating layer 34, a circuit pattern layer 36, and a solder mask layer 50. The copper platform bumps 32 and the circuit pattern layer 36 are all disposed on an upper surface of the substrate 40. Each of the copper platform bumps 32 has a part higher than a height of the circuit pattern layer 36. The solder mask layer 50 covers a part of the upper surface of the substrate 40, an upper surface of the circuit pattern layer 36, and upper surfaces of a part of the copper platform bumps 32. The plating layer 34 covers upper surfaces of the rest part of the copper platform bumps 32 which are not covered by the solder mask layer 50. The part of copper platform bumps 32 which are covered by the plating layer 34 are welded to the chip foot pads 10 disposed at the bottom of the chip 8 with a thermo-compression welding process. Then, the cladding material 7 is filled between the chip 8 and the FC platform structure 5. The chip foot pads 10 for example can be copper pillar bumps or gold stud bumps. The cladding material 7 for example can be under-fill or molding compound. The FC package structure 3 does not need to reserve a space for wire bonding and thus the area of the substrate can be saved, and the product can be made smaller. The copper platform bumps 32 are configured with a height higher than a height of the circuit pattern layer 36. In such a way, the chip 8 is blocked up, so that a gap d2 between the chip 8 and the substrate 40 is enlarged, thus preventing the risk of configuring voids when filling the cladding material 7 and improving the packaging yield.

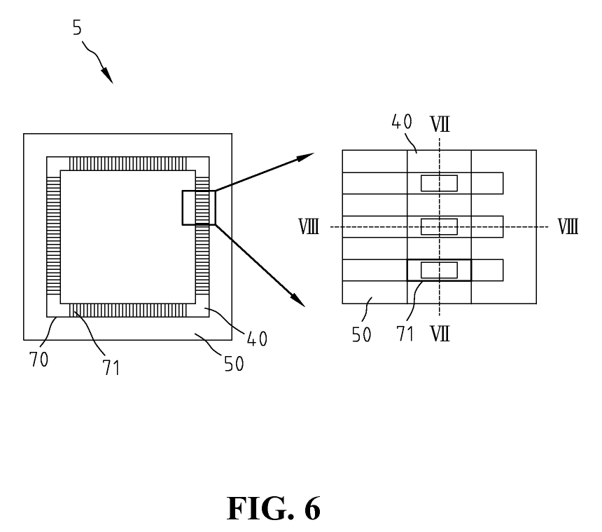

FIG. 6 is a schematic diagram of an embodiment of the present invention shown in FIG. 5. Referring to FIG. 6, the right drawing shows a partial enlargement detail of the left drawing. As shown in FIG. 6, the FP platform structure 5 includes a substrate 40, a peripheral FP pad region 70, and a solder mask layer 50. The peripheral FP pad region 70 includes a plurality of FP pads 71. The FP pads 71 are the part of copper platform bumps 32 which are covered by the plating layer 34. The solder mask layer 50 covers a part of the upper surface of the substrate 40, and upper surfaces of another part of the copper platform bumps 32.

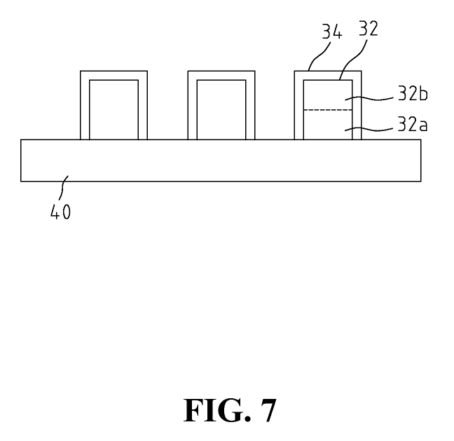

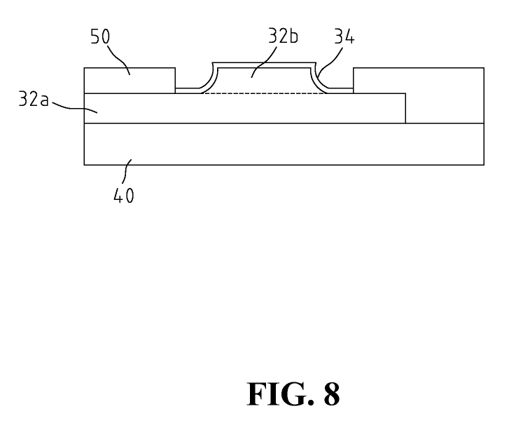

FIG. 7 is a longitudinal cross-sectional view of the embodiment of the present invention as shown in FIG. 6 along a line VII-VII. FIG. 8 is a latitudinal cross-sectional view of the embodiment of the present invention as shown in FIG. 6 along a line VIII-VIII. As shown in FIG. 7, the copper platform bumps 32 disposed on the substrate 40 each includes a copper bump 32a and a copper platform 32b. As shown in FIG. 8, the copper platform 32b is stacked on a part of the copper bump 32a. The copper platform 32b is protruded from the upper surface of the copper bump 32a for a certain height. The solder mask layer 50 covers the upper surface of the substrate 40 and the upper surfaces of a part of the copper bumps 32a. The plating layer 34 covers the copper platforms 32a and the rest part of the copper bumps 32a which are not covered by the solder mask layer 50 with a surface technology for metal processing. The surface technology for example can be plating tin, immersion tin, organic solderability preservative (OSP), electroless nickel and immersion gold (ENIG), or electroless nickel electroless palladium immersion gold (ENEPIG).

It should be noted that the dashed lines presented in FIGS. 7 and 8 are provided for convenience of depicting the relative positions of the copper bumps 32a and the copper platforms 32b. In fact, with respect to each copper platform bump 32, the copper bump 32a and the copper platform 32b are integrally configured.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A flip-chip (FC) package structure, comprising:
a chip, comprising a plurality of chip foot pads positioned at a bottom of the chip;
an FC platform structure, comprising:
a substrate;
a plurality of copper platform bumps, disposed on an upper surface of the substrate;
a circuit pattern layer, disposed on the upper surface of the substrate;
a solder mask layer, covering a part of the upper surface of the substrate, an upper surface of the circuit pattern layer, and upper surfaces of a part of the copper platform bumps; and
a plating layer, covering upper surfaces of the rest part of the copper platform bumps which are not covered by the solder mask layer by a surface technology for metal processing; and
a cladding material, filled between the chip and the FC platform structure.

2. The FC package structure according to claim 1, wherein each of the copper platform bumps comprises a copper bump and a copper platform, and the copper platform is stacked on a part of the upper surface of the copper bump.

3. The FC package structure according to claim 1, wherein an FC pad is configured at where the plating layer covers each of the copper platform bumps.

4. The FC package structure according to claim 3, wherein the chip foot pads are bonded with the FC pads, respectively, with a welding process.

5. The FC package structure according to claim 4, wherein the welding process is a thermo-compression welding process.

6. The FC package structure according to claim 1, wherein the surface technology is plating tin, immersion tin, organic solderability preservative (OSP), electroless nickel and immersion gold (ENIG), or electroless nickel electroless palladium immersion gold (ENEPIG).

7. The FC package structure according to claim 1, wherein each of the copper platform bumps has a part higher than a height of the circuit pattern layer.

8. The FC package structure according to claim 1, wherein the cladding material is an under-fill or molding compound.

9. The FC package structure according to claim 1, wherein the chip foot pads are copper pillar bumps or gold stud bumps.
